(19) United States
(12) Patent Application Publication
(10) Pub. No.: US 2026/0255990 A1
(43) Pub. Date: Aug. 27, 2026

(54) SEMICONDUCTOR PACKAGE AND MANUFACTURING METHOD THEREOF

(71) Applicant: Orient Semiconductor Electronics, Limited, Kaohsiung City (TW)

(72) Inventors: YUEH-MING TUNG, Kaohsiung City (TW); CHIA-MING YANG, Kaohsiung City (TW); PO-YEN YEN, Kaohsiung City (TW); GUAN-LIN PAN, Kaohsiung City (TW); TSUN-LUNG HSIEH, Kaohsiung City (TW)

(21) Appl. No.: 19/060,816

(22) Filed: Feb. 24, 2025

(30) Foreign Application Priority Data
Sep. 4, 2024 (TW) 113133555

(51) Int. Cl. H01L 23/538; H01L 21/56; H01L 23/00; H01L 23/31; H01L 23/367; H01L 25/07

(52) U.S. Cl. CPC H10W 70/611; H10W 40/22; H10W 72/075; H10W 74/01; H10W 90/401; H10W 72/072; H10W 72/241; H10W 72/879; H10W 74/117; H10W 90/00; H10W 90/724; H10W 90/754

(57) ABSTRACT

The present disclosure provides a semiconductor package. The semiconductor package includes a base substrate, an intermediate substrate, a plurality of first conductive bumps, a first die, and a plurality of second conductive bumps. The intermediate substrate is disposed on the base substrate. The first conductive bumps are disposed between and electrically connected to the base substrate and the intermediate substrate. The first die is disposed on the intermediate substrate. The second conductive bumps are disposed between and electrically connected to the intermediate substrate and the first die. The second conductive bumps are electrically connected to the first conductive bumps through the intermediate substrate. The present disclosure further provides a method of manufacturing the above semiconductor package.

### CROSS-REFERENCE TO RELATED APPLICATIONS

The present application is based on and claims priority to Taiwanese Application Number 113133555, filed Sep. 4, 2024, the disclosure of which is hereby incorporated by reference herein in its entirety.

### FIELD OF THE DISCLOSURE

This disclosure relates to a semiconductor package and a manufacturing method thereof, and more particularly relates to a semiconductor package having an intermediate substrate, and a manufacturing method thereof.

### BACKGROUND OF THE DISCLOSURE

At present, the manufacturing cost of high-computing semiconductor packages is too high and their yield is not easy to control.

### SUMMARY

In view of the above, the present disclosure provides a semiconductor package and a manufacturing method thereof to solve the above problems.

In one embodiment, the semiconductor package of the present disclosure includes a base substrate, an intermediate substrate, a plurality of first conductive bumps, a first die, and a plurality of second conductive bumps. The intermediate substrate is disposed on the base substrate. The first conductive bumps are disposed between and electrically connected to the base substrate and the intermediate substrate. The first die is disposed on the intermediate substrate. The second conductive bumps are disposed between and electrically connected to the intermediate substrate and the first die. The second conductive bumps are electrically connected to the first conductive bumps through the intermediate substrate.

In one embodiment, the method of manufacturing a semiconductor package comprises: forming a plurality of first conductive bumps on an intermediate substrate; disposing the intermediate substrate on a base substrate such that the first conductive bumps are disposed between the base substrate and the intermediate substrate and the first conductive bumps are electrically connected to the base substrate and the intermediate substrate; forming a plurality of second conductive bumps on a first die; and disposing the first die on the intermediate substrate such that the second conductive bumps are disposed between the intermediate substrate and the first die and the second conductive bumps are electrically connected to the intermediate substrate and the first die, wherein the second conductive bumps are electrically connected to the first conductive bumps through the intermediate substrate.

The semiconductor packages of the present disclosure have lower manufacturing costs and higher production yields.

The foregoing, as well as additional objects, features and advantages of the disclosure will be more readily apparent from the following detailed description, which proceeds with reference to the accompanying drawings.

### BRIEF DESCRIPTION OF DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a schematic diagram of the semiconductor package according to the first embodiment of the present disclosure.

FIG. 2 is a schematic diagram of the semiconductor package according to the second embodiment of the present disclosure.

FIGS. 3 to 11 illustrate the method of manufacturing the semiconductor package of FIG. 1.

FIGS. 12 to 23 illustrate the method of manufacturing the semiconductor package of FIG. 2.

### DETAILED DESCRIPTION OF THE DISCLOSURE

The following disclosure provides many different embodiments, or examples, for implementing different features of the disclosure. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatial relative terms, such as “beneath.” “below,” “lower,” “above,” “upper” and the like, may be used herein for ease of description to describe one element or feature's relationship to another element(s) or feature(s) as illustrated in the figures. The spatial relative terms are intended to encompass different orientations of the device in use or operation in addition to the orientation depicted in the figures. The apparatus may be otherwise oriented (rotated 90 degrees or at other orientations) and the spatial relative descriptors used herein may likewise be interpreted accordingly.

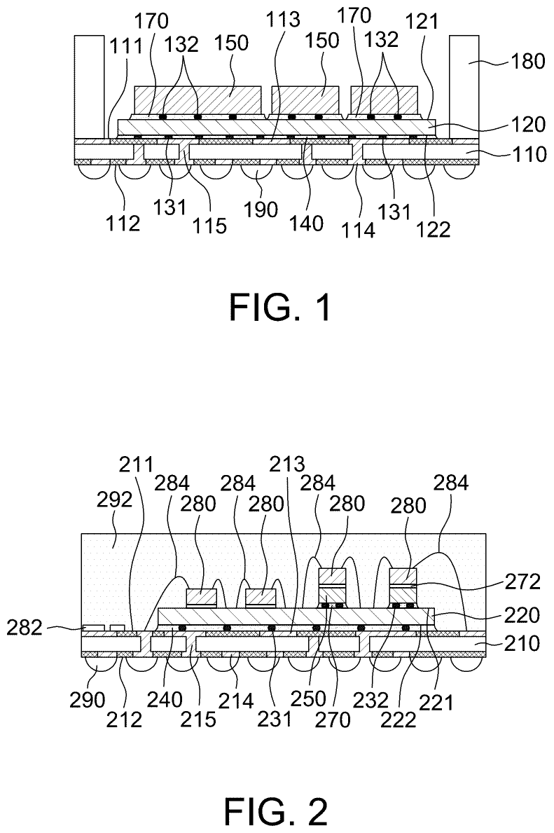

Referring to FIG. 1, the semiconductor package of the present disclosure according to the first embodiment includes a base substrate 110. The base substrate 110 may be a single-layer or multi-layer circuit board, but is not limited thereto. The base substrate 110 has opposing first surface 111 and second surface 112, and the first surface 111 and the second surface 112 are located on different planes. For example, the first surface 111 is a top surface and the second surface 112 is a bottom surface, but is not limited thereto. The first surface 111 and the second surface 112 of the base substrate 110 are formed with a conductive trace 113 and a conductive trace 114 thereon, respectively. The conductive traces 113 and 114 are electrically connected to each other by a plurality of conductive vias 115 penetrating the base substrate 110 from the first surface 111 to the second surface 112.

An intermediate substrate 120 is positioned on the first surface 111 of the base substrate 110. The intermediate substrate 120 may be constructed of silicon, glass or other materials. The intermediate substrate 120 has opposing first surface 121 and second surface 122, and the first surface 121 and the second surface 122 are located on different planes. For example, the first surface 121 is a top surface and the second surface 122 is a bottom surface, but is not limited thereto.

The first surface 121 and the second surface 122 of the intermediate substrate 120 are formed with conductive traces thereon, respectively, which are electrically connected to each other by a plurality of conductive vias (not shown in the figure) penetrating the intermediate substrate 120 from the first surface 121 to the second surface 122. A plurality of first conductive bumps 131 is disposed on the second surface 122 of the intermediate substrate 120 and sandwiched between the intermediate substrate 120 and the base substrate 110. The intermediate substrate 120 is electrically connected to the base substrate 110 through the first conductive bumps 131. A gap between the intermediate substrate 120 and the base substrate 110 is infiltrated with underfill 140 to cover the first conductive bumps 131. In addition, a plurality of passive components may be mounted on the first surface 111 of the base substrate 110 as desired.

In one embodiment, the intermediate substrate 120 may be formed by cutting a silicon wafer, and conductive traces are provided on two opposite surfaces of the silicon wafer to form the conductive traces on the first surface 121 and the second surface 122 of the intermediate substrate 120, respectively. In another embodiment, the first conductive bumps 131 are metal bumps formed on the second surface 122 of the intermediate substrate 120 using a bumping process. The first conductive bumps 131 may be composed of eutectic, lead free, high lead materials, or copper pillars. The intermediate substrate 120 is attached to the first surface 111 of the base substrate 110 using flip chip technology.

At least one, for example, a plurality of dies 150 is disposed side by side on the first surface 121 of the intermediate substrate 120. The dies 150 each have an active surface and a back surface opposite to the active surface. A plurality of second conductive bumps 132 is disposed on the active surface of each of the dies 150. The second conductive bumps 132 are electrically connected to the dies 150 respectively. The second conductive bumps 132 are sandwiched between the dies 150 and the intermediate substrate 120. The second conductive bumps 132 are electrically connected to the first conductive bumps 131 through the conductive traces on the first surface 121 and the second surface 122 of the intermediate substrate 120, so that the dies 150 may be electrically connected to the base substrate 110. Gaps between the dies 150 and the intermediate substrate 120 are infiltrated with underfill 170 to cover the second conductive bumps 132.

In one embodiment, the second conductive bumps 132 are metal bumps formed on the active surfaces of the dies 150 using a bumping process. The second conductive bumps 132 may be composed of eutectic, lead free, high lead materials, or copper pillars. The dies 150 are attached to the first surface 121 of the intermediate substrate 120 using flip chip technology.

A heat-dissipating frame 180 is disposed on the first surface 111 of the base substrate 110 to surround the intermediate substrate 120 and the dies 150. In addition, a plurality of solder balls 190 is disposed on the second surface 112 of the base substrate 110 and electrically connected to the base substrate 110. The solder balls 190 are electrically connected to the first conductive bumps 131 through the conductive traces 113, 114, and the conductive vias 115 on the base substrate 110, so that the dies 150 may be electrically connected to an external circuit through the intermediate substrate 120 and the base substrate 110 using the solder balls 190.

Referring to FIG. 2, the semiconductor package of the present disclosure according to the second embodiment includes a base substrate 210. The base substrate 210 may be a single-layer or multi-layer circuit board, but is not limited thereto. The base substrate 210 has opposing first surface 211 and second surface 212, and the first surface 211 and the second surface 212 are located on different planes. For example, the first surface 211 is a top surface and the second surface 212 is a bottom surface, but is not limited thereto. The first surface 211 and the second surface 212 of the base substrate 210 are formed with a conductive trace 213 and a conductive trace 214 thereon, respectively. The conductive traces 213 and 214 are electrically connected to each other by a plurality of conductive vias 215 penetrating the base substrate 210 from the first surface 211 to the second surface 212.

An intermediate substrate 220 is positioned on the first surface 211 of the base substrate 210. The intermediate substrate 220 may be constructed of silicon, glass or other materials. The intermediate substrate 220 has opposing first surface 221 and second surface 222, and the first surface 221 and the second surface 222 are located on different planes. For example, the first surface 221 is a top surface and the second surface 222 is a bottom surface, but is not limited thereto.

The first surface 221 and the second surface 222 of the intermediate substrate 220 are formed with conductive traces thereon, respectively, which are electrically connected to each other by a plurality of conductive vias (not shown in the figure) penetrating the intermediate substrate 220 from the first surface 221 to the second surface 222. A plurality of first conductive bumps 231 is disposed on the second surface 222 of the intermediate substrate 220 and sandwiched between the intermediate substrate 220 and the base substrate 210. The intermediate substrate 220 is electrically connected to the base substrate 210 through the first conductive bumps 231. A gap between the intermediate substrate 220 and the base substrate 210 is infiltrated with underfill 240 to cover the first conductive bumps 231. In addition, a plurality of passive components 282 may be mounted on the first surface 211 of the base substrate 210 as desired.

In one embodiment, the intermediate substrate 220 may be formed by cutting a silicon wafer, and conductive traces are provided on two opposite surfaces of the silicon wafer to form the conductive traces on the first surface 221 and the second surface 222 of the intermediate substrate 220, respectively. In another embodiment, the first conductive bumps 231 are metal bumps formed on the second surface 222 of the intermediate substrate 220 using a bumping process. The first conductive bumps 231 may be composed of eutectic, lead free, high lead materials, or copper pillars. The intermediate substrate 220 is attached to the first surface 211 of the base substrate 210 using flip chip technology.

At least one, for example, a plurality of first dies 250 is disposed side by side on the first surface 221 of the intermediate substrate 220. The first dies 250 each have an active surface and a back surface opposite to the active surface. A plurality of second conductive bumps 232 is disposed on the active surface of each of the first dies 250. The second conductive bumps 232 are electrically connected to the first dies 250 respectively. The second conductive bumps 232 are sandwiched between the first dies 250 and the intermediate substrate 220. The second conductive bumps 232 are electrically connected to the first conductive bumps 231 through the conductive traces on the first surface 221 and the second surface 222 of the intermediate substrate 220, so that the first dies 250 may be electrically connected to the base substrate 210. Gaps between the first dies 250 and the intermediate substrate 220 are infiltrated with underfill 270 to cover the second conductive bumps 232.

In one embodiment, the second conductive bumps 232 are metal bumps formed on the active surfaces of the first dies 250 using a bumping process. The second conductive bumps 232 may be composed of eutectic, lead free, high lead materials, or copper pillars. The first dies 250 are attached to the first surface 221 of the intermediate substrate 220 using flip chip technology.

At least one, for example, a plurality of second dies 280 is disposed on the first dies 250. The second dies 280 each have an active surface and a back surface opposite to the active surface. The back surfaces of the second dies 280 are respectively attached to the back surfaces of the first dies 250 using silver adhesive or die attach film (DAF) 272.

In another embodiment, the second dies 280 may be disposed on the first surface 221 of the intermediate substrate 210. The back surfaces of the second dies 280 are attached to the first surface 221 of the intermediate substrate 210 using silver adhesive or die attach film.

The second dies 280 are electrically connected to the first surface 211 of the base substrate 210 or the first surface 221 of the intermediate substrate 220 by means of a plurality of bonding wires 284, i.e., the respective ends of the bonding wires 284 are connected to the active surfaces of the second dies 280 and the first surface 211 of the base substrate 210 or the first surface 221 of the intermediate substrate 220. Therefore, the second dies 280 are electrically connected to the intermediate substrate 220 or the base substrate 210 through the bonding wires 284. A molding layer 292 is formed on the first surface 211 of the base substrate 210 to cover the intermediate substrate 220, the passive components 282, the first dies 250, the second dies 280 and the bonding wires 284.

In addition, a plurality of solder balls 290 is disposed on the second surface 212 of the base substrate 210 and electrically connected to the base substrate 210. The solder balls 290 are electrically connected to the first conductive bumps 231 through the conductive traces 213, 214, and the conductive vias 215 on the base substrate 210, so that the first dies 250 may be electrically connected to an external circuit through the intermediate substrate 220 and the base substrate 210 using the solder balls 290. Similarly, the solder balls 290 are electrically connected to the bonding wires 284 through the conductive traces 213, 214, and the conductive vias 215 on the base substrate 210, so that the second dies 280 may be electrically connected to an external circuit through the bonding wires 284, the intermediate substrate 220 and the base substrate 210 using the solder balls 290.

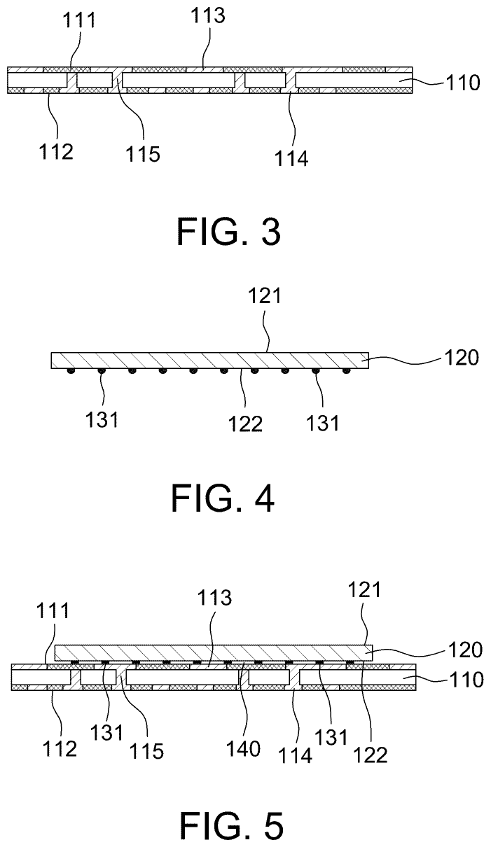

Referring to FIGS. 3 to 11, which illustrate a method of manufacturing the semiconductor package of FIG. 1. As shown in FIG. 3, a base substrate 110 is provided. The base substrate 110 may be a single-layer or multi-layer circuit board, but is not limited thereto. The base substrate 110 has opposing first surface 111 and second surface 112, and the first surface 111 and the second surface 112 are located on different planes. For example, the first surface 111 is a top surface and the second surface 112 is a bottom surface, but is not limited thereto. The first surface 111 and the second surface 112 of the base substrate 110 are formed with a conductive trace 113 and a conductive trace 114 thereon, respectively. The conductive traces 113 and 114 are electrically connected to each other by a plurality of conductive vias 115 penetrating the base substrate 110 from the first surface 111 to the second surface 112. In addition, a plurality of passive components may be mounted on the first surface 111 of the base substrate 110 as desired.

As shown in FIG. 4, an intermediate substrate 120 is provided and it may be constructed of silicon, glass or other materials. The intermediate substrate 120 has opposing first surface 121 and second surface 122, and the first surface 121 and the second surface 122 are located on different planes. For example, the first surface 121 is a top surface and the second surface 122 is a bottom surface, but is not limited thereto. The first surface 121 and the second surface 122 of the intermediate substrate 120 are formed with conductive traces thereon, respectively, which are electrically connected to each other by a plurality of conductive vias (not shown in the figure) penetrating the intermediate substrate 120 from the first surface 121 to the second surface 122. A plurality of first conductive bumps 131 is disposed on the second surface 122 of the intermediate substrate 120 and electrically connected to the intermediate substrate 120.

In one embodiment, the intermediate substrate 120 may be formed by cutting a silicon wafer, and conductive traces are provided on two opposite surfaces of the silicon wafer to form the conductive traces on the first surface 121 and the second surface 122 of the intermediate substrate 120, respectively. In another embodiment, the first conductive bumps 131 are metal bumps formed on the second surface 122 of the intermediate substrate 120 using a bumping process. The first conductive bumps 131 may be composed of eutectic, lead free, high lead materials, or copper pillars.

As shown in FIG. 5, the intermediate substrate 120 is then attached to the first surface 111 of the base substrate 110 using flip chip technology such that the first conductive bumps 131 are sandwiched between the intermediate substrate 120 and the base substrate 110. The intermediate substrate 120 is electrically connected to the base substrate 110 through the first conductive bumps 131.

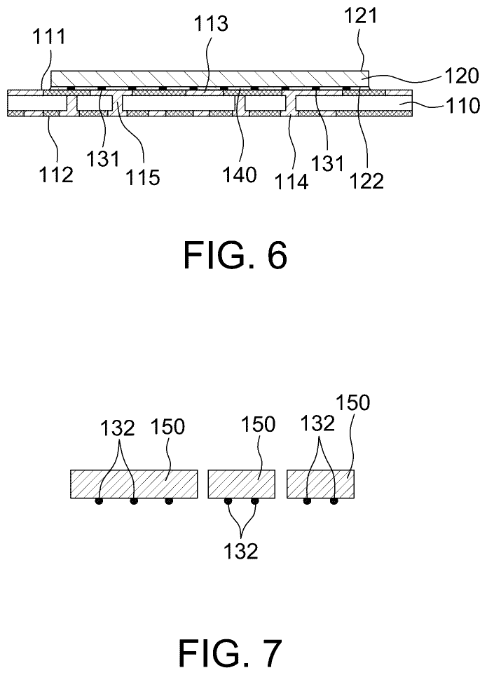

As shown in FIG. 6, a gap between the intermediate substrate 120 and the base substrate 110 is then infiltrated with underfill 140 to cover the first conductive bumps 131.

As shown in FIG. 7, at least one, for example, a plurality of dies 150 is provided. The dies 150 each have an active surface and a back surface opposite to the active surface. A plurality of second conductive bumps 132 is disposed on the active surface of each of the dies 150. The second conductive bumps 132 are electrically connected to the dies 150 respectively. In one embodiment, the second conductive bumps 132 are metal bumps formed on the active surfaces of the dies 150 using a bumping process. The second conductive bumps 132 may be composed of eutectic, lead free, high lead materials, or copper pillars.

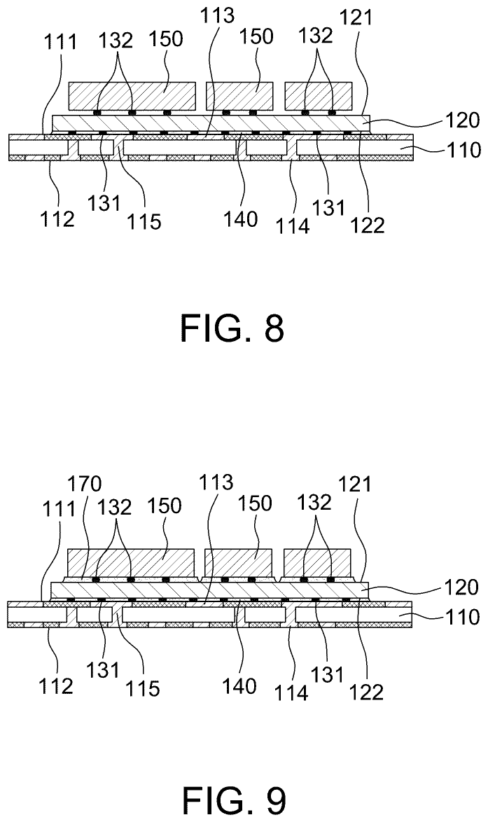

As shown in FIG. 8, the dies 150 are then attached to the first surface 121 of the intermediate substrate 120 using flip chip technology such that the second conductive bumps 132 are sandwiched between the dies 150 and the intermediate substrate 120. The second conductive bumps 132 are electrically connected to the first conductive bumps 131 through the conductive traces on the first surface 121 and the second surface 122 of the intermediate substrate 120, so that the dies 150 may be electrically connected to the base substrate 110.

As shown in FIG. 9, gaps between the dies 150 and the intermediate substrate 120 are then infiltrated with underfill 170 to cover the second conductive bumps 132.

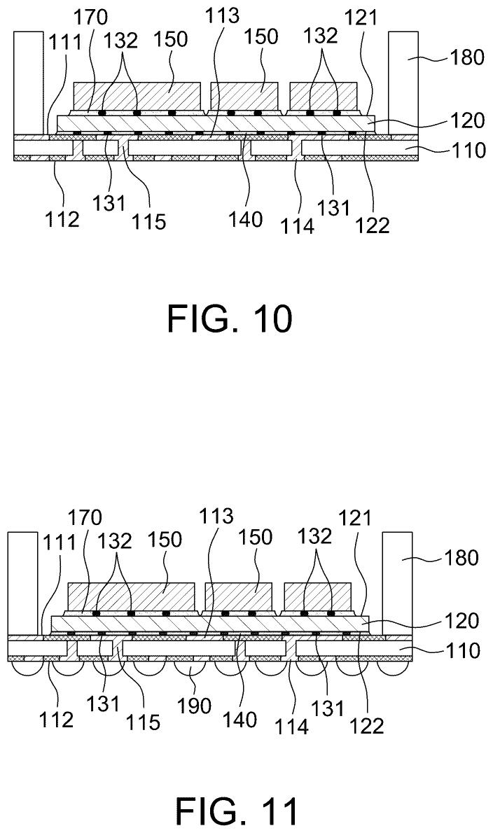

As shown in FIG. 10, a heat-dissipating frame 180 is then disposed on the first surface 111 of the base substrate 110 to surround the intermediate substrate 120 and the dies 150.

As shown in FIG. 11, a plurality of solder balls 190 is then disposed on the second surface 112 of the base substrate 110 and electrically connected to the base substrate 110 so as to form the semiconductor package of FIG. 1.

The solder balls 190 are electrically connected to the first conductive bumps 131 through the conductive traces 113, 114, and the conductive vias 115 on the base substrate 110, so that the dies 150 may be electrically connected to an external circuit through the intermediate substrate 120 and the base substrate 110 using the solder balls 190.

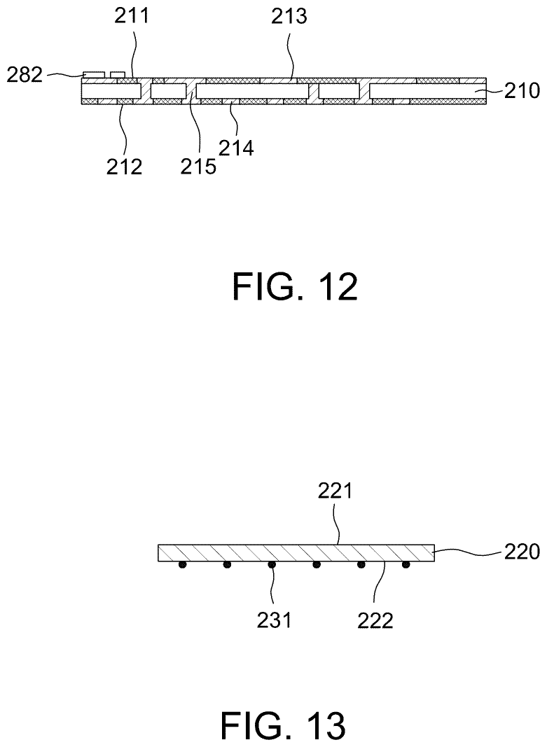

Referring to FIGS. 12 to 23, which illustrate a method of manufacturing the semiconductor package of FIG. 2. As shown in FIG. 12, a base substrate 210 is provided. The base substrate 210 may be a single-layer or multi-layer circuit board, but is not limited thereto. The base substrate 210 has opposing first surface 211 and second surface 212, and the first surface 211 and the second surface 212 are located on different planes. For example, the first surface 211 is a top surface and the second surface 212 is a bottom surface, but is not limited thereto. The first surface 211 and the second surface 212 of the base substrate 210 are formed with a conductive trace 213 and a conductive trace 214 thereon, respectively. The conductive traces 213 and 214 are electrically connected to each other by a plurality of conductive vias 215 penetrating the base substrate 210 from the first surface 211 to the second surface 212. In addition, a plurality of passive components 282 may be mounted on the first surface 211 of the base substrate 210 as desired.

As shown in FIG. 13, an intermediate substrate 220 is provided and it may be constructed of silicon, glass or other materials. The intermediate substrate 220 has opposing first surface 221 and second surface 222, and the first surface 221 and the second surface 222 are located on different planes. For example, the first surface 221 is a top surface and the second surface 222 is a bottom surface, but is not limited thereto. The first surface 221 and the second surface 222 of the intermediate substrate 220 are formed with conductive traces thereon, respectively, which are electrically connected to each other by a plurality of conductive vias (not shown in the figure) penetrating the intermediate substrate 220 from the first surface 221 to the second surface 222. A plurality of first conductive bumps 231 is disposed on the second surface 222 of the intermediate substrate 220 and electrically connected to the intermediate substrate 220.

In one embodiment, the intermediate substrate 220 may be formed by cutting a silicon wafer, and conductive traces are provided on two opposite surfaces of the silicon wafer to form the conductive traces on the first surface 221 and the second surface 222 of the intermediate substrate 220, respectively. In another embodiment, the first conductive bumps 231 are metal bumps formed on the second surface 222 of the intermediate substrate 220 using a bumping process. The first conductive bumps 231 may be composed of eutectic, lead free, high lead materials, or copper pillars.

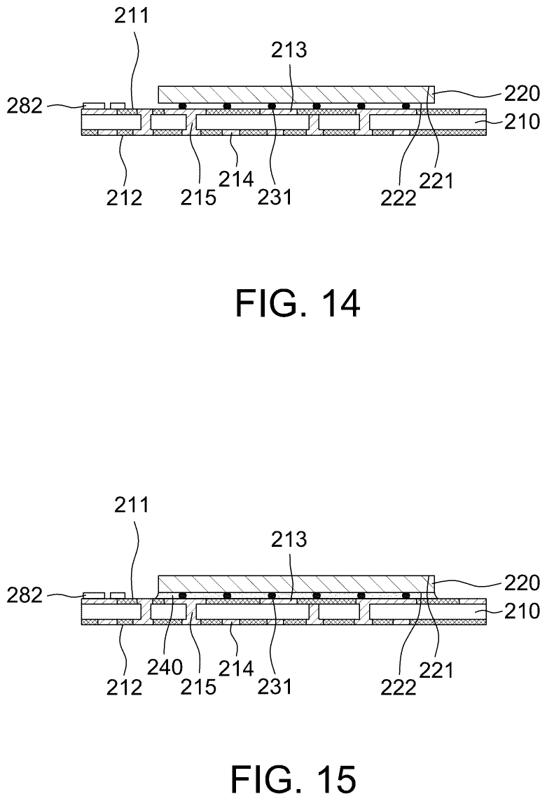

As shown in FIG. 14, the intermediate substrate 220 is then attached to the first surface 211 of the base substrate 210 using flip chip technology such that the first conductive bumps 231 are sandwiched between the intermediate substrate 220 and the base substrate 210. The intermediate substrate 220 is electrically connected to the base substrate 210 through the first conductive bumps 231.

As shown in FIG. 15, a gap between the intermediate substrate 220 and the base substrate 210 is then infiltrated with underfill 240 to cover the first conductive bumps 231.

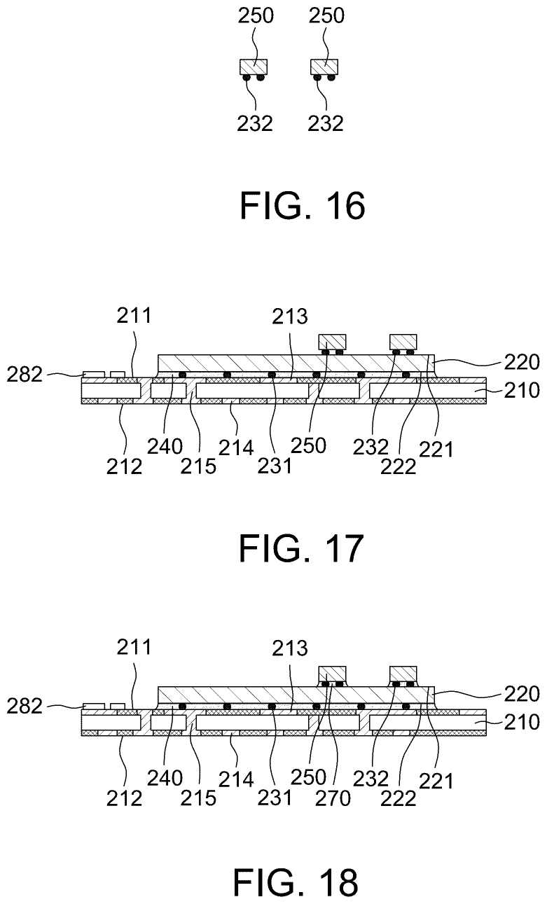

As shown in FIG. 16, at least one, for example, a plurality of first dies 250 is provided. The first dies 250 each have an active surface and a back surface opposite to the active surface. A plurality of second conductive bumps 232 is disposed on the active surface of each of the first dies 250. The second conductive bumps 232 are electrically connected to the first dies 250 respectively. In one embodiment, the second conductive bumps 232 are metal bumps formed on the active surfaces of the first dies 250 using a bumping process. The second conductive bumps 232 may be composed of eutectic, lead free, high lead materials, or copper pillars.

As shown in FIG. 17, the first dies 250 are then attached to the first surface 221 of the intermediate substrate 220 using flip chip technology such that the second conductive bumps 232 are sandwiched between the first dies 250 and the intermediate substrate 220. The second conductive bumps 232 are electrically connected to the first conductive bumps 231 through the conductive traces on the first surface 221 and the second surface 222 of the intermediate substrate 220, so that the first dies 250 may be electrically connected to the base substrate 210.

As shown in FIG. 18, gaps between the first dies 250 and the intermediate substrate 220 are then infiltrated with underfill 270 to cover the second conductive bumps 232.

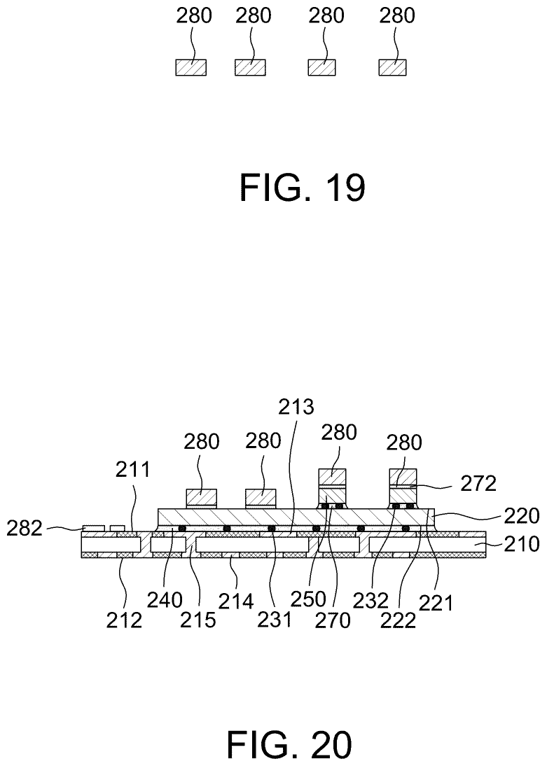

As shown in FIG. 19, at least one, for example, a plurality of second dies 280 is provided. The second dies 280 each have an active surface and a back surface opposite to the active surface.

As shown in FIG. 20, the second dies 280 are then disposed on the first dies 250. The back surfaces of the second dies 280 are respectively attached to the back surfaces of the first dies 250 using silver adhesive or die attach film (DAF) 272.

In another embodiment, the second dies 280 may be disposed on the first surface 221 of the intermediate substrate 210. The back surfaces of the second dies 280 are attached to the first surface 221 of the intermediate substrate 210 using silver adhesive or die attach film.

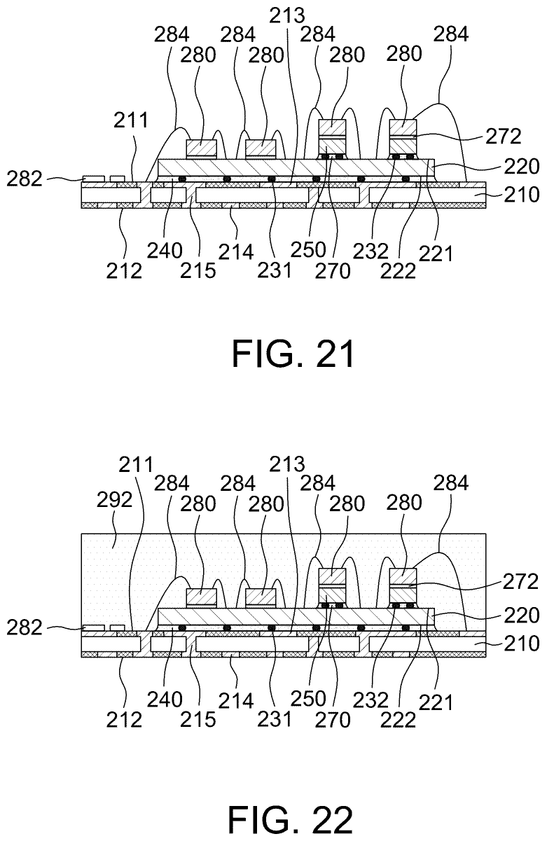

As shown in FIG. 21, the second dies 280 are then electrically connected to the first surface 211 of the base substrate 210 or the first surface 221 of the intermediate substrate 220 by means of a plurality of bonding wires 284. The respective ends of the bonding wires 284 are connected to the active surfaces of the second dies 280 and the first surface 211 of the base substrate 210 or the first surface 221 of the intermediate substrate 220. Therefore, the second dies 280 are electrically connected to the intermediate substrate 220 or the base substrate 210 through the bonding wires 284.

As shown in FIG. 22, a molding layer 292 is then formed on the first surface 211 of the base substrate 210 to cover the intermediate substrate 220, the passive components 282, the first dies 250, the second dies 280 and the bonding wires 284.

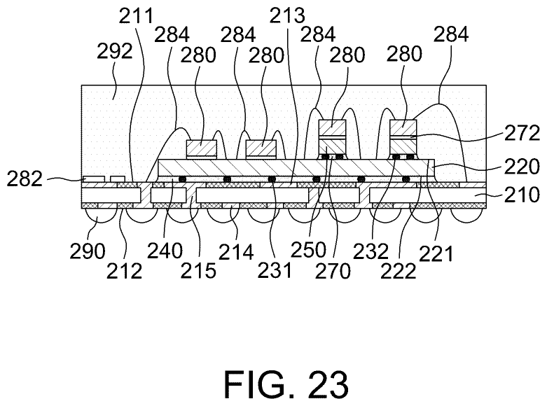

As shown in FIG. 23, a plurality of solder balls 290 is then disposed on the second surface 212 of the base substrate 210 and electrically connected to the base substrate 210 so as to form the semiconductor package of FIG. 2.

The solder balls 290 are electrically connected to the first conductive bumps 231 through the conductive traces 213, 214, and the conductive vias 215 on the base substrate 210, so that the first dies 250 may be electrically connected to an external circuit through the intermediate substrate 220 and the base substrate 210 using the solder balls 290. Similarly, the solder balls 290 are electrically connected to the bonding wires 284 through the conductive traces 213, 214, and the conductive vias 215 on the base substrate 210, so that the second dies 280 may be electrically connected to an external circuit through the bonding wires 284, the intermediate substrate 220 and the base substrate 210 using the solder balls 290.

The semiconductor packages of the present disclosure have lower manufacturing costs and higher production yields.

Although the preferred embodiments of the disclosure have been disclosed for illustrative purposes, those skilled in the art will appreciate that various modifications, additions and substitutions are possible, without departing from the scope and spirit of the disclosure as disclosed in the accompanying claims.

1. A semiconductor package, comprising:
a base substrate;
an intermediate substrate disposed on the base substrate;
a plurality of first conductive bumps disposed between the base substrate and the intermediate substrate, the first conductive bumps being electrically connected to the base substrate and the intermediate substrate;
a first die disposed on the intermediate substrate; and
a plurality of second conductive bumps disposed between the intermediate substrate and the first die, the second conductive bumps being electrically connected to the intermediate substrate and the first die,
wherein the second conductive bumps are electrically connected to the first conductive bumps through the intermediate substrate.

2. The semiconductor package as claimed in claim 1, further comprising:
a heat-dissipating frame disposed on the base substrate to surround the intermediate substrate and the first die.

3. The semiconductor package as claimed in claim 1, further comprising:
a second die attached to the first die or the intermediate substrate;
a plurality of bonding wires, one end of each of the bonding wires being connected to the second die, and the other end of each of the bonding wires being connected to the base substrate or the intermediate substrate; and
a molding layer formed on the base substrate to cover the first die, the second die and the bonding wires.

4. A method of manufacturing a semiconductor package, comprising:
forming a plurality of first conductive bumps on an intermediate substrate;
disposing the intermediate substrate on a base substrate such that the first conductive bumps are disposed between the base substrate and the intermediate substrate and the first conductive bumps are electrically connected to the base substrate and the intermediate substrate;
forming a plurality of second conductive bumps on a first die; and
disposing the first die on the intermediate substrate such that the second conductive bumps are disposed between the intermediate substrate and the first die and the second conductive bumps are electrically connected to the intermediate substrate and the first die,
wherein the second conductive bumps are electrically connected to the first conductive bumps through the intermediate substrate.

5. The method as claimed in claim 4, further comprising:
disposing a heat-dissipating frame on the base substrate to surround the intermediate substrate and the first die.

6. The method as claimed in claim 4, further comprising:
attaching a second die to the first die or the intermediate substrate;
disposing a plurality of bonding wires such that one end of each of the bonding wires is connected to the second die and the other end of each of the bonding wires is connected to the base substrate or the intermediate substrate; and
forming a molding layer on the base substrate to cover the first die, the second die and the bonding wires.

7. The method as claimed in claim 4, further comprising:
filling an underfill in a gap between the intermediate substrate and the base substrate to cover the first conductive bumps.

8. The method as claimed in claim 4, wherein the intermediate substrate is constructed of silicon or glass.

9. The method as claimed in claim 4, wherein the intermediate substrate is attached to the base substrate by flip chip technology.

10. The method as claimed in claim 6, wherein the second die is attached to the first die by silver adhesive or die attach film.
